(19) United States
(12) Patent Application Publication
(10) Pub. No.: US 2025/0133936 A1
(43) Pub. Date: Apr. 24, 2025

(54) DISPLAYING BASE BOARD AND DISPLAYING DEVICE

(71) Applicants: Chengdu BOE Optoelectronics Technology Co., Ltd., Chengdu, Sichuan (CN); BOE Technology Group Co., Ltd., Beijing (CN)

(72) Inventors: Quanyong Gu, Beijing (CN); Tiaomei Zhang, Beijing (CN); Ziyang Yu, Beijing (CN); Wenbo Chen, Beijing (CN); Pan Zhao, Beijing (CN); Mengqi Wang, Beijing (CN); Erjin Zhao, Beijing (CN); Xiangnan Pan, Beijing (CN); Qingqing Yan, Beijing (CN); Qing He, Beijing (CN); Zhiliang Jiang, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/683,690

(22) PCT Filed: Feb. 28, 2023
(86) PCT No.: PCT/CN2023/078762

§ 371 Date: Feb. 14, 2024

(51) Int. Cl. H10K 59/80; H10K 59/131

(52) U.S. Cl. CPC H10K 59/873; H10K 59/131

(57) ABSTRACT

A displaying base board includes an active area and a peripheral region, the peripheral region includes at least a first blocking part and a second blocking part; the peripheral region further includes a first power-supply signal line, and an orthographic projection of the first power-supply signal line on a substrate of the displaying base board has an overlapping part with individually an orthographic projection of the first blocking part on the substrate and an orthographic projection of the second blocking part on the substrate; and the first power-supply signal line is provided with a plurality of openings, and a region enclosed by orthographic projections on the substrate of outer contours of some of the openings falls within a region of the orthographic projection on the substrate of at least one of the first blocking part and the second blocking part.

### TECHNICAL FIELD

The present application relates to the technical field of displaying and more particularly, to a displaying base board and a displaying device.

### BACKGROUND

With the rapid development of the displaying technology, narrow-border-frame display products have gradually become hotspot products popular in people due to their characteristics of a high screen-to-body ratio and a good aesthetics. However, because of the narrow border frame of the display products, the room in their border-frame region for the provision of the traces, the components and other film-layer structures is reduced. Because of the shrinking of the room, in one hand, it increases the difficulty in the fabrication process. In the other hand, it very easily results in abnormality in the traces, the components and other film-layer structures in the border-frame region, which deteriorates the quality of the display products.

### SUMMARY

The embodiments of the present application employ the following technical solutions:

In the first aspect, at least one embodiment of the present application provides a displaying base board, wherein the displaying base board comprises an active area and a peripheral region located on one side of the active area, the peripheral region comprises at least a first blocking part and a second blocking part, and the second blocking part is located on one side of the first blocking part away from the active area;
the peripheral region further comprises a first power-supply signal line, and an orthographic projection of the first power-supply signal line on a substrate of the displaying base board has an overlapping part with individually an orthographic projection of the first blocking part on the substrate and an orthographic projection of the second blocking part on the substrate; and
the first power-supply signal line is provided with a plurality of openings, and a region enclosed by orthographic projections on the substrate of outer contours of some of the openings falls within a region of the orthographic projection on the substrate of at least one of the first blocking part and the second blocking part.

In at least one embodiment of the present application, the displaying base board comprises a first conductive layer and a second conductive layer located on one side of the first conductive layer away from the substrate;
the first power-supply signal line comprises a first conductive part and a second conductive part, the first conductive part is located at the first conductive layer, the second conductive part is located at the second conductive layer, and an orthographic projection of the first conductive part on the substrate and an orthographic projection of the second conductive part on the substrate partially overlap; and
an area of an orthographic projection on the substrate of an outer contour of the second conductive part is greater than or equal to two times of an area of an orthographic projection on the substrate of an outer contour of the first conductive part.

In at least one embodiment of the present application, the orthographic projection of the first conductive part on the substrate partially overlaps with the orthographic projection of the first blocking part on the substrate and the orthographic projection of the second blocking part on the substrate individually, and the orthographic projection of the second conductive part on the substrate partially overlaps with the orthographic projection of the first blocking part on the substrate and the orthographic projection of the second blocking part on the substrate individually.

In at least one embodiment of the present application, in a direction perpendicular to a plane where the substrate is located, a height of the first blocking part is less than or equal to a height of the second blocking part.

In at least one embodiment of the present application, the peripheral region comprises a first peripheral sub-region, the first peripheral sub-region is located on one side of the active area, the first peripheral sub-region comprises a plurality of shift-register units that are cascaded, and the first blocking part is located on one side of the shift-register units away from the active area; and
in the direction perpendicular to the plane where the substrate is located, a height of a part of the first blocking part that is located in the first peripheral sub-region is substantially equal to a height of a part of the second blocking part that is located in the first peripheral sub-region.

In at least one embodiment of the present application, the first conductive part and part of a conducting component in the shift-register units are arranged in a same layer, and the second conductive part covers at least some of the shift-register units.

In at least one embodiment of the present application, in the first peripheral sub-region, a region enclosed by orthographic projections on the substrate of outer contours of some of the openings falls within orthographic projections of the shift-register units on the substrate, and a region enclosed by orthographic projections on the substrate of outer contours of some of the openings falls within a region of the orthographic projection of the first blocking part on the substrate.

In at least one embodiment of the present application, a part of the first conductive part that is located in the first peripheral sub-region comprises a first edge and a second edge, the first edge is close to the active area, the second edge is away from the active area, and an orthographic projection of the second edge on the substrate and an orthographic projection of the second blocking part on the substrate overlap; and
the displaying base board further comprises a first organic layer located between the first conductive layer and the second conductive layer, and the first organic layer covers the first edge and the second edge.

In at least one embodiment of the present application, the peripheral region comprises a first peripheral sub-region, a second peripheral sub-region and a transition sub-region connecting the first peripheral sub-region and the second peripheral sub-region;
the first peripheral sub-region comprises a plurality of shift-register units, and the second peripheral sub-region comprises a bonding electrode; and
in the second peripheral sub-region and part of the transition sub-region, along the direction perpendicular to the plane where the substrate is located, the height of the first blocking part is less than the height of the second blocking part.

In at least one embodiment of the present application, the transition sub-region comprises a first region and a second region that are connected, the first region is connected to the first peripheral sub-region, and the second region is connected to the second peripheral sub-region; and
the first conductive part extends from the first peripheral sub-region to the first region, and the second conductive part extends from the first peripheral sub-region to the first region, the second region and the second peripheral sub-region.

In at least one embodiment of the present application, on one side of the first region that is close to the second region, a line width of the first conductive part gradually decreases in a direction from the first region pointing to the second region.

In at least one embodiment of the present application, on the one side of the first region that is close to the second region, a line width of the second conductive part gradually decreases in the direction from the first region pointing to the second region.

In at least one embodiment of the present application, in the first region, an amplitude of the decreasing of the line width of the first conductive part and an amplitude of the decreasing of the line width of the second conductive part are consistent.

In at least one embodiment of the present application, the first power-supply signal line further comprises a third conductive part, the third conductive part extends from the second region to the second peripheral sub-region, and the third conductive part is located at the second conductive layer, and is connected to the second conductive part;
an orthographic projection of the third conductive part on the substrate partially overlaps with the orthographic projection of the second blocking part on the substrate, and the second blocking part is located at a boundary between the second conductive part and the third conductive part; and
in the second region, a line width of the third conductive part gradually increases in a direction from the second region pointing to the second peripheral sub-region.

In at least one embodiment of the present application, in the second region, an amplitude of the increasing of the line width of the third conductive part and an amplitude of the decreasing of the line width of the second conductive part are consistent.

In at least one embodiment of the present application, in the first region, the orthographic projection of the first conductive part on the substrate partially overlaps with the orthographic projection of the first blocking part on the substrate, and the first conductive part is located on one side of the first blocking part that is close to the active area;
a region enclosed by orthographic projections on the substrate of outer contours of some of the openings falls within a region of the orthographic projection of the first blocking part on the substrate; and
a region enclosed by orthographic projections on the substrate of outer contours of some of the openings falls within a region of the second conductive part that does not overlap with the orthographic projection of the first conductive part on the substrate.

In at least one embodiment of the present application, in the second region and the second peripheral sub-region, a region enclosed by orthographic projections on the substrate of outer contours of some of the openings falls within the orthographic projection of the second conductive part on the substrate; and
a region enclosed by orthographic projections on the substrate of outer contours of some of the openings falls within a region of the orthographic projection of the second blocking part on the substrate.

In at least one embodiment of the present application, the third conductive part comprises a third edge and a fourth edge, the third edge is close to the active area, the fourth edge is away from the active area, and an orthographic projection of the third edge on the substrate and the orthographic projection of the second blocking part on the substrate overlap; and
the displaying base board further comprises a second organic layer located on one side of the second conductive layer away from the substrate, and the second organic layer covers the third edge and the fourth edge.

In at least one embodiment of the present application, in the first peripheral sub-region, both of the first blocking part and the second blocking part comprise:
part of the first conductive part located on the substrate;
part of the first organic layer directly contacting the first conductive part; and
part of the second conductive part, part of the second organic layer, part of an anode layer, part of a pixel defining layer and part of a buffer layer that are located on the first organic layer and are sequentially arranged; and
in a region between the first blocking part and the second blocking part, the first conductive part and the second conductive part directly contact, and the second conductive part and the anode layer directly contact.

In at least one embodiment of the present application, in the second region of the transition sub-region and the second peripheral sub-region, the first blocking part comprises:
part of the second conductive part located on the substrate, part of the second organic layer, and part of the pixel defining layer covering the second organic layer; and
the second blocking part comprises:
part of the first organic layer; and
part of the second conductive part, part of the second organic layer and part of the pixel defining layer that are located on the first organic layer and are sequentially arranged.

In the second aspect, at least one embodiment of the present application provides a displaying device, wherein the displaying device comprises the displaying base board according to any one of the embodiments in the first aspect.

The above description is merely a summary of the technical solutions of the present application. In order to more clearly know the elements of the present application to enable the implementation according to the contents of the description, and in order to make the above and other purposes, features and advantages of the present application more apparent and understandable, the particular embodiments of the present application are provided below.

### BRIEF DESCRIPTION OF THE DRAWINGS

In order to more clearly illustrate the technical solutions of the embodiments of the present application or the related art, the figures that are required to describe the embodiments or the related art will be briefly described below. Apparently, the figures that are described below are merely embodiments of the present application, and a person skilled in the art can obtain other figures according to these figures without paying creative work.

FIGS. 1 and 2 are schematic structural top views of first peripheral regions of two types of displaying base board according to the embodiments of the present application;

FIG. 3 is a schematic structural cross-sectional view along a direction A1A2 of FIG. 2;

FIG. 4 is a schematic structural top view of the transition sub-region of a displaying base board according to an embodiment of the present application;

FIGS. 5 and 6 are two partially enlarged schematic diagrams of FIG. 4;

FIG. 7 is a schematic structural cross-sectional view along a direction A3A4 of FIG. 6;

FIG. 8 is a schematic structural cross-sectional view along a direction A5A6 of FIG. 6;

FIG. 9 is a schematic structural top view of the connection position of a transition sub-region and a second peripheral sub-region according to an embodiment of the present application;

FIG. 10 is a schematic structural top view of a second peripheral sub-region according to an embodiment of the present application;

FIG. 11 is a partially enlarged schematic diagram of FIG. 10; and

FIG. 12 is a schematic structural cross-sectional view along a direction A7A8 of FIG. 11.

### DETAILED DESCRIPTION

The technical solutions of the embodiments of the present application will be clearly and completely described below with reference to the drawings of the embodiments of the present application. Apparently, the described embodiments are merely certain embodiments of the present application, rather than all of the embodiments. All of the other embodiments that a person skilled in the art obtains on the basis of the embodiments of the present application without paying creative work fall within the protection scope of the present application.

In the embodiments of the present application, unless stated otherwise, the meaning of “plurality of” is “two or more”. The terms that indicate orientation or position relations, such as “upper”, are based on the orientation or position relations shown in the drawings, and are merely for conveniently describing the present application and simplifying the description, rather than indicating or implying that the component or element must have the specific orientation and be constructed and operated according to the specific orientation. Therefore, they should not be construed as a limitation on the present application.

Unless stated otherwise in the context, throughout the description and the claims, the term “comprise” is interpreted as the meaning of opened containing, i.e., “including but not limited to”. In the description of the present disclosure, the terms “one embodiment”, “some embodiments”, “exemplary embodiments”, “example”, “specific example” or “some examples” are intended to indicate that specific features, structures, materials or characteristics related to the embodiment or example are comprised in at least one embodiment or example of the present application. The illustrative indication of the above terms does not necessarily refer to the same embodiment or example. Moreover, the specific features, structures, materials or characteristics may be comprised in any one or more embodiments or examples in any suitable manner.

In the embodiments of the present application, terms such as “first” and “second” are used to distinguish identical items or similar items that have substantially the same functions and effects, merely in order to clearly describe the technical solutions of the embodiments of the present application, and should not be construed as indicating or implying the degrees of importance or implicitly indicating the quantity of the specified technical features.

All of the features used in the embodiments of the present application of “parallel”, “perpendicular”, “the same” and so on include the features of “parallel”, “perpendicular”, “the same” and so on in the strict sense, and include the cases of a certain error such as “substantially parallel”, “substantially perpendicular” and “substantially the same”, taking into consideration the measurement and the errors relevant to the measurement on particular quantities (for example, restricted by the measuring system), and represent that they are in the acceptable deviation ranges of the particular values determined by a person skilled in the art. For example, the “substantially” can represent that they are within one or more standard deviations, or within 10% or 5% of the values. “At least one” refers to “one or more”, and “plurality of” refers to “at least two”.

The “same layer” according to the embodiments of the present application refers to “formed by using the same material after the same step (for example, a one-step patterning step)”. The “same layer” used herein does not always refer to that the thickness of a plurality of film layers are equal or that the heights in a cross-sectional view of a plurality of film layers are equal.

The polygons in the description are not the strictly defined polygons, may be an approximate triangle, parallelogram, trapezoid, pentagon, hexagon and so on, and may have some small deformations caused by tolerance.

In recent years, with the development of the technique of displaying, organic light emitting displays (Organic Light Emitting Diode, OLED) are one of the hotspots of the research field of flat-panel displays nowadays, and increasingly Active Matrix Organic Light Emitting Diode (AMOLED) display panels have entered the market. As compared with traditional Thin-Film-Transistor Liquid-Crystal Display Panels (TFTLCD), the AMOLED display panels have a higher response speed, a higher contrast and a wider visual angle.

In addition, narrow-border-frame display products have gradually become hotspot products popular in people due to their characteristics of a high screen-to-body ratio and a good aesthetics. However, because of the narrow border frame of the display products, the room within their border-frame region for the provision of the traces, the components and other film-layer structures is reduced. Because of the shrinking of the room, in one hand, it increases the difficulty in the fabrication process. In the other hand, it very easily results in abnormality in the traces, the components and other film-layer structures within the border-frame region, which deteriorates the quality of the display products.

In view of that, the embodiments of the present application provide a displaying base board and a displaying device, wherein the displaying base board comprises an active area and a peripheral region located on one side of the active area, the peripheral region comprises at least a first blocking part and a second blocking part, and the second blocking part is located on the side of the first blocking part away from the active area; the peripheral region further comprises a first power-supply signal line, and the orthographic projection of the first power-supply signal line on a substrate of the displaying base board has an overlapping part with individually the orthographic projection of the first blocking part on the substrate and the orthographic projection of the second blocking part on the substrate; and the first power-supply signal line is provided with a plurality of openings, and the region enclosed by the orthographic projections on the substrate of the outer contours of some of the openings falls within the region of the orthographic projection on the substrate of at least one of the first blocking part and the second blocking part. The embodiments of the present application provide a layout structure of a part of the displaying base board which is located in the peripheral region. By configuring that the orthographic projection of the first power-supply signal line on the substrate of the displaying base board has an overlapping part with individually the orthographic projection of the first blocking part on the substrate and the orthographic projection of the second blocking part on the substrate, the size of the first power-supply signal line is increased, the electric conductivity of the first power-supply signal line is increased, and the resistance of the first power-supply signal line is reduced, thereby improving the effect of the signal transmission in the first power-supply signal line. By providing the plurality of openings in the first power-supply signal line, and configuring that the region enclosed by the orthographic projections on the substrate of the outer contours of some of the openings falls within the region of the orthographic projection on the substrate of at least one of the first blocking part and the second blocking part, the gases generated by the organic materials of the first blocking part and the second blocking part can be released out of the openings, thereby preventing the first power-supply signal line from sealing the gases generated by the organic materials to result in abnormality of the displaying base board.

The displaying base board and the displaying device according to the embodiments of the present application will be described particularly below with reference to the drawings.

At least one embodiment of the present application provides a displaying base board, wherein the displaying base board comprises an active area AA and a peripheral region BB surrounding the active area AA, the peripheral region BB comprises at least a first blocking part Dam1 and a second blocking part Dam2, and the second blocking part Dam2 is located on the side of the first blocking part Dam1 away from the active area AA.

The peripheral region BB further comprises a first power-supply signal line (for example, a line VSS), and the orthographic projection of the first power-supply signal line on a substrate 100 of the displaying base board has an overlapping part with individually the orthographic projection of the first blocking part Dam1 on the substrate 100 and the orthographic projection of the second blocking part Dam2 on the substrate 100.

The first power-supply signal line (for example, a line VSS) is provided with a plurality of openings SD2-H, and the region enclosed by the orthographic projections on the substrate 100 of the outer contours of some of the openings SD2-H falls within the region of the orthographic projection on the substrate 100 of at least one of the first blocking part Dam1 and the second blocking part Dam2.

In an exemplary embodiment, the displaying base board may be applied to an OLED display panel.

In some examples, the substrate 100 may be fabricated by using one or more of glass, polyimide, polycarbonate, polyacrylate, polyetherimide and polyether sulfone, and the present embodiment includes but is not limited thereto.

In some examples, the substrate 100 may be a rigid substrate or a flexible substrate.

If the substrate 100 is a flexible substrate, the substrate 100 may comprise a single flexible-material layer, or the substrate 100 may comprise a first flexible-material layer, a first inorganic non-metallic material layer, a second flexible-material layer and a second inorganic non-metallic material layer that are arranged sequentially in stack. The materials of the first flexible-material layer and the second flexible-material layer employ the materials such as polyimide (PI), polyethylene terephthalate (PET) and a surface-treated polymer soft film. The materials of the first inorganic non-metallic material layer and the second inorganic non-metallic material layer employ silicon nitride (SiNx), silicon oxide (SiOx) and so on, to improve the capacity of the substrate of resisting water and oxygen. The first inorganic non-metallic material layer and the second inorganic non-metallic material layer are also referred to as barrier layers.

If the substrate 1 is a rigid substrate, the substrate 1 may include a glass substrate or a silicon-material substrate.

The active area AA refers to the region that can actually display frames when the displaying base board is fabricated to form a display panel. The active area AA has a plurality of pixels arranged in an array, which can realize the function of displaying.

The peripheral region BB surrounds the active area AA, and, in the peripheral region BB, by providing a driving IC (Driver IC) and a flexible circuit board (FPC), various signals for displaying are supplied to the active area AA, for example, a data signal (Data signal), a grid controlling signal (Gate), a light-emission controlling signal (EM), an initializing signal (Vini), an anode power-supply signal (VDD) and a cathode power-supply signal (VSS).

In at least one embodiment of the present application, the first blocking part Dam1 surrounds the active area AA, and the second blocking part Dam2 surrounds the first blocking part Dam1. It can be understood that both of the patterns of the orthographic projections on the substrate 100 of the first blocking part Dam1 and the second blocking part Dam2 are annular.

In at least one embodiment of the present application, the peripheral region BB comprises but is not limited to the first blocking part Dam1 and the second blocking part Dam2. As an example, the peripheral region BB comprises at least two blocking parts. For example, the peripheral region BB comprises the first blocking part Dam1 and the second blocking part Dam2, and the second blocking part Dam2 surrounds the first blocking part Dam1. It may further comprise a third blocking part Dam3, the third blocking part Dam3 surrounds the second blocking part Dam2, all of the patterns of the orthographic projections on the substrate 100 of the first blocking part Dam1, the second blocking part Dam2 and the third blocking part Dam3 are annular.

In at least one embodiment of the present application, the first blocking part Dam1 surrounds the active area AA, the second blocking part Dam2 surrounds the first blocking part Dam1, and the first blocking part Dam1 and the second blocking part Dam2 may be disconnected in the second peripheral sub-region B3.

In practical applications, if an organic sublayer (IJP layer) in an encapsulation layer TFE is formed on the displaying base board by ink-jet printing, in order to prevent the printed ink from flowing out of the edge of the displaying base board, the first blocking part Dam1 can effectively prevent the printed ink from flowing out, and the second blocking part Dam2 can further prevent the ink from flowing out, thereby preventing failure of the blocking of the first blocking part Dam1.

In an exemplary embodiment, each of the first blocking part Dam1 and the second blocking part Dam2 comprises at least two organic film layers, for example, at least two of a first organic layer PLN1, a second organic layer PLN2, a pixel defining layer PDL and a buffer layer PS.

The first power-supply signal line may comprise a cathode power-supply voltage line VSS.

In addition, the meaning of “having an overlapping part with” is “at least partially overlapping”, wherein the “at least partially overlapping” includes the two cases of “partially overlapping” and “wholly overlapping”.

The first power-supply signal line (for example, the cathode power-supply voltage line VSS) is provided with a plurality of openings SD2-H, the openings SD2-H penetrate the conductive film layer where they are located, and the openings expose the film-layer structures under the conductive film layer where they are located.

In an exemplary embodiment, that the region enclosed by the orthographic projections on the substrate 100 of the outer contours of some of the openings SD2-H falls within the region of the orthographic projection on the substrate 100 of at least one of the first blocking part Dam1 and the second blocking part Dam2 includes but is not limited to the following cases:

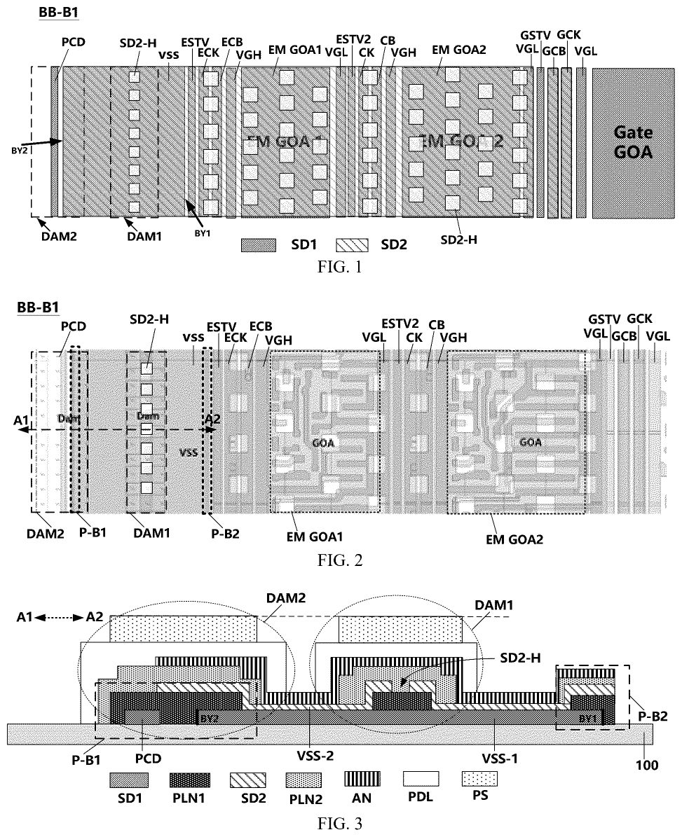

In the first case, within some of the regions of the peripheral region BB, for example, as in the schematic structural diagrams of the first peripheral region B1 of the peripheral region BB shown in FIGS. 1 and 2, in the first peripheral region B1, the region enclosed by the orthographic projections on the substrate 100 of the outer contours of some of the openings SD2-H falls within the region of the orthographic projection on the substrate 100 of the first blocking part Dam1.

The first peripheral region B1 comprises the border-frame region on the left side and the right side of the active area AA.

In the second case, in some of the regions of the peripheral region BB, for example, as shown in FIG. 10, in the second peripheral sub-region B3, the region enclosed by the orthographic projections on the substrate 100 of the outer contours of some of the openings SD2-H falls within the region of the orthographic projection on the substrate 100 of the second blocking part Dam2.

The second peripheral region B3 comprises the border-frame region on the lower side of the active area AA, and the second peripheral sub-region B3 may be provided with a bonding electrode.

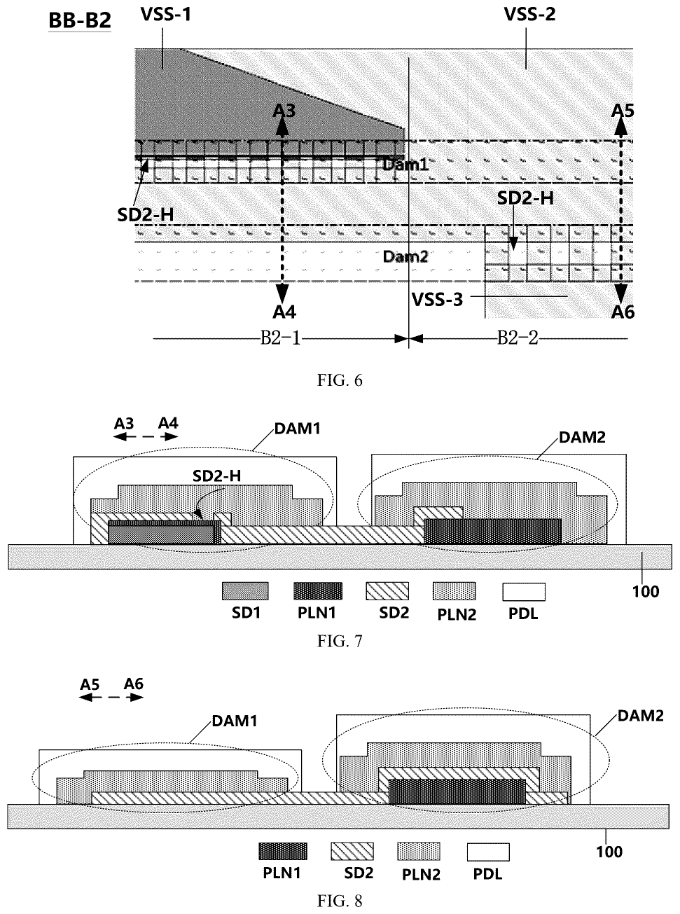

In the third case, within some of the regions of the peripheral region BB, for example, as shown in FIG. 6, within the transition sub-region B2, the region enclosed by the orthographic projections on the substrate 100 of the outer contours of some of the openings SD2-H falls within the region of the orthographic projection on the substrate 100 of the first blocking part Dam1, and the region enclosed by the orthographic projections on the substrate 100 of the outer contours of some of the openings SD2-H falls within the region of the orthographic projection on the substrate 100 of the second blocking part Dam2.

The transition sub-region B2 is the region between the border-frame region on the left side of the active area AA and the border-frame region on the lower side of the active area AA or the region between the border-frame region on the right side of the active area AA and the border-frame region on the lower side of the active area AA.

The embodiments of the present application provide a displaying base board. In the displaying base board, by configuring that the orthographic projection of the first power-supply signal line, for example, the line VSS, on the substrate 100 of the displaying base board has an overlapping part with individually the orthographic projection of the first blocking part Dam1 on the substrate 100 and the orthographic projection of the second blocking part Dam2 on the substrate 100, the size of the first power-supply signal line is increased, the electric conductivity of the first power-supply signal line is increased, and the resistance of the first power-supply signal line is reduced, thereby improving the effect of the signal transmission in the first power-supply signal line. By providing the plurality of openings (for example, those labeled as SD2-H) in the first power-supply signal line, for example, the line VSS, and configuring that the region enclosed by the orthographic projections on the substrate 100 of the outer contours of some of the openings falls within the region of the orthographic projection on the substrate 100 of at least one of the first blocking part Dam1 and the second blocking part Dam2, the gases (Bubble) generated by the organic materials of the first blocking part Dam1 and the second blocking part Dam2 can be released out of the openings, thereby preventing the first power-supply signal line from sealing the gases generated by the organic materials to result in abnormality of the displaying base board.

In the related art, the VDD (anode power-supply signal line) and the VSS (cathode power-supply signal line) of the border-frame region of the OLED display panel influence both of the effect of displaying and the luminous efficiency to a large extent. With the prevalence of narrow-border-frame display products, the traces in the border-frame region (for example, the VSS traces) are compressed with the reduction of the room. However, the compression of the design space of the VSS traces (for example, the width of the traces, which is also referred to as the line width) tends to bring risks. The reduction of the width of the traces means the increasing of the resistance, which affects the uniformity of the displaying brightness of the display panel. Furthermore, the increasing of the resistance means the increasing of the heat generation, which, in an aging test, easily results in heat accumulation and thus results in burning at local region, to damage the display panel.

In view of that, in at least one embodiment of the present application, the displaying base board comprises a first conductive layer and a second conductive layer located on the side of the first conductive layer away from the substrate 100. The first power-supply signal line comprises a first conductive part VSS-1 and a second conductive part VSS-2, the first conductive part VSS-1 is located at the first conductive layer, the second conductive part VSS-2 is located at the second conductive layer, and the orthographic projection of the first conductive part VSS-1 on the substrate 100 and the orthographic projection of the second conductive part VSS-2 on the substrate 100 partially overlap. The area of the orthographic projection on the substrate 100 of the outer contour of the second conductive part VSS-2 is greater than or equal to two times of the area of the orthographic projection on the substrate 100 of the outer contour of the first conductive part VSS-1.

The materials of the first conductive layer and the second conductive layer are not limited herein. As an example, each of the materials of the first conductive layer and the second conductive layer may include at least one of alloy, metal and metal oxide.

For example, if the displaying base board comprises two source-drain metal layers, the first conductive layer may be a first source-drain metal layer SD1, and the second conductive layer may be a second source-drain metal layer SD2.

As another example, if the displaying base board comprises two source-drain metal layers, the first conductive layer may be a second source-drain metal layer SD2, and the second conductive layer may be an anode layer AN.

As another example, if the displaying base board comprises one source-drain metal layer, the first conductive layer may be a source-drain metal layer SD1, and the second conductive layer may be an anode layer AN.

The drawings of the description are drawn and illustrate by taking the case as an example in which the first conductive layer is a first source-drain metal layer SD1 and the second conductive layer is a second source-drain metal layer SD2.

It should be noted that the first conductive part VSS-1 and the second conductive part VSS-2 are electrically connected. For example, within part of the region where the orthographic projections of the first conductive part VSS-1 and the second conductive part VSS-2 overlap, the first conductive part VSS-1 and the second conductive part VSS-2 are directly contacted and connected.

In the displaying base board according to the embodiments of the present application, by configuring that the first power-supply signal line comprises a first conductive part VSS-1 and a second conductive part VSS-2, and configuring that the area of the orthographic projection on the substrate 100 of the outer contour of the second conductive part VSS-2 is greater than or equal to two times of the area of the orthographic projection on the substrate 100 of the outer contour of the first conductive part VSS-1, the size of the first power-supply signal line is further increased, the electric conductivity of the first power-supply signal line is increased, and the resistance of the first power-supply signal line is reduced, thereby improving the effect of the signal transmission in the first power-supply signal line.

In at least one embodiment of the present application, as shown in FIG. 3, the orthographic projection of the first conductive part VSS-1 on the substrate 100 partially overlaps with the orthographic projection of the first blocking part Dam1 on the substrate 100 and the orthographic projection of the second blocking part Dam2 on the substrate 100 individually, and the orthographic projection of the second conductive part VSS-2 on the substrate 100 partially overlaps with the orthographic projection of the first blocking part Dam1 on the substrate 100 and the orthographic projection of the second blocking part Dam2 on the substrate 100 individually.

In the embodiment of the present application, by configuring that the first conductive part VSS-1 partially overlaps with the first blocking part Dam1 and the second blocking part Dam2 individually, and the second conductive part VSS-2 partially overlaps with the first blocking part Dam1 and the second blocking part Dam2 individually, in an aspect, the size of the first power-supply signal line is increased, and the electric conductivity of the first power-supply signal line is increased. In another aspect, by configuring that the first conductive part VSS-1 and the second conductive part VSS-2 individually serve as part of the film layers that form the blocking parts (including the first blocking part Dam1 and the second blocking part Dam2), the heights of the first blocking part Dam1 and the second blocking part Dam2 are increased, which can improve the effect of the blocking to the printed ink by the first blocking part Dam1 and the second blocking part Dam2.

In at least one embodiment of the present application, in the direction perpendicular to the plane where the substrate 100 is located, the height of the first blocking part Dam1 is less than or equal to the height of the second blocking part Dam2.

As an example, as shown in FIGS. 1, 2 and 3, in the first peripheral sub-region B1 (the first peripheral sub-region B1 comprises a plurality of shift-register units that are cascaded), in the displaying base boards of some narrow-border-frame display products, because the size of the border frame is reduced, if an organic sublayer (IJP layer) in a encapsulation layer TFE is formed on the displaying base board by ink-jet printing, the possibility with which the printed ink flows out of the edge of the displaying base board is changed. In order to prevent such a problem, it may be configured that, in the direction perpendicular to the plane where the substrate 100 is located, the height of the first blocking part Dam1 is substantially equal to the height of the second blocking part Dam2, thereby improving the effect of the blocking by the blocking parts.

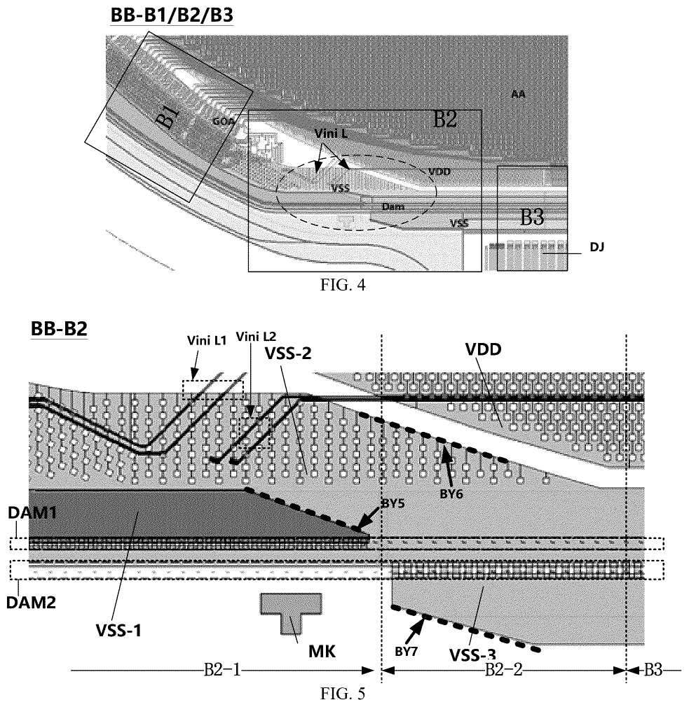

As an example, as shown in FIG. 4, in part of the transition sub-region B2 (for example, the second region B2-2, see the following description particularly) and the second peripheral sub-region B3, in the direction perpendicular to the plane where the substrate 100 is located, the height of the first blocking part Dam1 is less than the height of the second blocking part Dam2. The region marked by the rectangular block at the middle position in FIG. 4 is the transition sub-region B2, and the border-frame region on the right side of the transition sub-region B2 is the second peripheral sub-region B3. Because, in the transition sub-region B2 and the second peripheral sub-region B3, the room between the edge of the active area AA and the edge of the displaying base board is larger than the room within the first peripheral sub-region B1, in the second peripheral sub-region B3 and part of the transition sub-region B2, the possibility with which the ink flows out of the edge of the displaying base board is reduced. Therefore, in this case, it may be configured that, in the direction perpendicular to the plane where the substrate 100 is located, the height of the first blocking part Dam1 is less than the height of the second blocking part Dam2. Accordingly, the consumption of the organic material of the peripheral region BB is reduced, thereby reducing the risk in abnormality of the displaying base board caused by the gas generated by the organic material.

In at least one embodiment of the present application, as shown in FIGS. 1 and 2, the peripheral region BB comprises a first peripheral sub-region B1, the first peripheral sub-region B1 is located on one side of the active area AA, the first peripheral sub-region B1 comprises a plurality of shift-register units GOA that are cascaded, and the first blocking part Dam1 is located on the side of the shift-register units GOA away from the active area AA. As shown in FIG. 3, in the direction perpendicular to the plane where the substrate 100 is located, the height of the part of the first blocking part Dam1 that is located in the first peripheral sub-region B1 is substantially equal to the height of the part of the second blocking part Dam2 that is located in the first peripheral sub-region B1. FIG. 3 is a cross-sectional view along a direction A1A2 of FIG. 2.

It should be noted that, in the description, the “substantially equal to” includes but is not limited to “equal to”, and all of fluctuations in the process range, for example, fluctuations in the range of 3%-5%, are within the protection scope of the present application.

In at least one embodiment of the present application, within the first peripheral sub-region B1, as shown in FIG. 3, both of the first blocking part Dam1 and the second blocking part Dam2 comprise:
part of the first conductive part VSS-1 located on the substrate 100;
part of the first organic layer PLN1 directly contacting the first conductive part VSS-1; and
part of the second conductive part VSS-2, part of the second organic layer PLN2, part of the anode layer AN, part of the pixel defining layer PDL and part of the buffer layer PS that are located on the first organic layer PLN1 and are sequentially arranged.

In the region between the first blocking part Dam1 and the second blocking part Dam2, the first conductive part VSS-1 and the second conductive part VSS-2 directly contact, and the second conductive part VSS-2 and the anode layer AN directly contact.

It should be noted that, in the displaying base board according to the embodiments of the present application, there is not provided an inorganic layer (for example, a PVX layer fabricated by using a PVD process) between the first conductive layer and the first organic layer, and therefore part of the first organic layer PLN1 can directly contact the first conductive part VSS-1. The omission of the PVX process (PVD process) can save the production time, and can reduce the material cost.

In an exemplary embodiment, one stage of the shift-register units can comprise a plurality of shift registers. For example, as shown in FIG. 1, one stage of the shift-register units may comprise two light-emission controlling shift registers EM GOA1, EM GOA2 and one grid controlling shift register Gate GOA. Both of the two light-emission controlling shift registers are located on the side of the grid controlling shift register away from the active area AA. One stage of the shift-register units is electrically connected to at least one line of the sub-pixels within the active area AA.

In an exemplary embodiment, as shown in FIG. 1 and FIG. 2, the first peripheral sub-region B1 further comprises a plurality of signal lines; for example, it comprises, without limitation, the following four parts:

The first part is a first enabling-signal line ESTV, a first clock-signal line ECK, a second clock-signal line ECB and a first high-level-signal line VGH that are located on the side of the first light-emission controlling shift register EM GOA1 away from the active area AA.

The second part is a first low-level-signal line VGL, a second enabling-signal line ESTV2, a third clock-signal line CK, a fourth clock-signal line CB and a second high-level-signal line VGH that are located between the first light-emission controlling shift register EM GOA1 and the second light-emission controlling shift register EM GOA2.

The third part is a second low-level-signal line VGL, a third enabling-signal line GSTV, a fifth clock-signal line GCB, a sixth clock-signal line GCK and a third low-level-signal line VGL that are located between the second light-emission controlling shift register EM GOA2 and the grid controlling shift register Gate GOA.

The fourth part is a detection line PCD located on the side of the first power-supply signal line VSS away from the active area AA, wherein the detection line PCD is located in the first conductive layer (for example, the layer SD1), and the orthographic projection of the detection line PCD on the substrate 100 is located within the orthographic projection of the second blocking part Dam2 on the substrate 100.

It should be noted that, as shown in FIG. 1, the fifth clock-signal line GCB and the sixth clock-signal line GCK located between the second light-emission controlling shift register EM GOA2 and the grid controlling shift register Gate GOA employ the configuration of double-conductive-layer wiring.

In at least one embodiment of the present application, as shown in FIG. 1 and FIG. 2, the first conductive part VSS-1 and part of the conducting component in the shift-register units are arranged in the same layer, and the second conductive part VSS-2 covers at least some of the shift-register units.

The “arranged in the same layer” refers to “formed by using the same material after the same step (for example, a one-step patterning step)”.

As an example, in FIG. 1, both of the first conductive part VSS-1 and part of the conducting component in the shift-register units are located in the first source-drain metal layer SD1, and the second conductive part VSS-2 is located in the second source-drain metal layer SD2.

As an example, that the second conductive part VSS-2 covers at least some of the shift-register units includes but is not limited to the following cases:

In the first case, the second conductive part VSS-2 covers some of the shift-register units.

For example, as shown in FIG. 1, if the fifth clock-signal line GCB and the sixth clock-signal line GCK between the second light-emission controlling shift register EM GOA2 and the grid controlling shift register Gate GOA employ the configuration of double-conductive-layer wiring, the second conductive part VSS-2 covers the first light-emission controlling shift register EM GOA1 and the second light-emission controlling shift register EM GOA2, and, in addition, the second conductive part VSS-2 covers the first conductive part VSS-1, covers the signal lines between the first conductive part VSS-1 and the first light-emission controlling shift register EM GOA1, and covers the signal lines between the first light-emission controlling shift register EM GOAL and the second light-emission controlling shift register EM GOA2.

In the second case, the second conductive part VSS-2 covers all of the shift-register units.

For example, if the fifth clock-signal line GCB and the sixth clock-signal line GCK between the second light-emission controlling shift register EM GOA2 and the grid controlling shift register Gate GOA employ the configuration of single-conductive-layer wiring (for example, the wiring is performed by using the first source-drain metal layer SD1), the second conductive part VSS-2 covers the first light-emission controlling shift register EM GOA1, the second light-emission controlling shift register EM GOA2 and the grid controlling shift register Gate GOA.

In at least one embodiment of the present application, as shown in FIG. 1 and FIG. 2, in the first peripheral sub-region B1, the region enclosed by the orthographic projections on the substrate 100 of the outer contours of some of the openings (for example, the openings labeled as SD2-H) falls within the orthographic projections of the shift-register units on the substrate 100, and the region enclosed by the orthographic projections on the substrate 100 of the outer contours of some of the openings (for example, the openings labeled as SD2-H) falls within the region of the orthographic projection of the first blocking part Dam1 on the substrate.

The shape of the patterns of the orthographic projections on the substrate 100 of the outer contours of the openings is not limited herein. As an example, as shown in FIG. 1 and FIG. 2, the shape may be a quadrangle, and, certainly, may also be a circle, an ellipse, a pentagon, a hexagon and a combination of a polygon and an arc shape, wherein the arc shape includes but is not limited to a circle and an ellipse.

The size of the openings is not limited herein.

For example, if the region enclosed by the orthographic projections on the substrate 100 of the outer contours of the openings falls within the region of the orthographic projection on the substrate of the first blocking part Dam1, the size of the openings may be decided according to the size of the first blocking part Dam1, and the size of each of the openings is less than the width of the first blocking part Dam1 in the direction from the active area AA pointing to the peripheral region BB.

As another example, if the region enclosed by the orthographic projections on the substrate 100 of the outer contours of the openings falls within the orthographic projections of the shift-register units on the substrate 100, the size of that part of the openings may be greater than the size of the openings that have an overlapping part with the first blocking part Dam1.

As another example, as shown in FIG. 1, if the region enclosed by the orthographic projections on the substrate 100 of the outer contours of the openings has an overlapping part with the other signal lines than the VSS signal line (for example, the line STV, the line CK, the line CB, the line VGH and the line VGL), the size of that part of the openings may be greater than the line widths (Width) of the signal lines.

In the displaying base board according to the embodiments of the present application, by configuring that the second conductive part VSS-2 covers at least some of the shift-register units, or, in other words, in the first peripheral region B1, the second conductive part VSS-2 extends from a position over the first conductive part VSS-1 to the position where the shift-register units are located, which increases the size and the area of the first power-supply signal line to a large extent, reduces the resistance of the first power-supply signal line to a large extent, increases the uniformity of the signal transmission, and increases the brightness uniformity of the displayed frames. In addition, by providing the openings in the second conductive part VSS-2 over the first blocking part Dam1 and over the shift-register units, the gases (Bubble) generated by the organic film layers underlying the second conductive layer (for example, SD2) can be released to a large extent, to further improve the quality of the displaying base board.

In at least one embodiment of the present application, referring to FIG. 2 and FIG. 3, the part of the first conductive part VSS-1 that is located in the first peripheral sub-region B1 comprises a first edge BY1 and a second edge BY2, the first edge BY1 is close to the active area AA, the second edge BY2 is away from the active area AA, and the orthographic projection of the second edge BY2 on the substrate 100 and the orthographic projection of the second blocking part Dam2 on the substrate 100 overlap. As shown in FIG. 3, the displaying base board further comprises the first organic layer PLN1 located between the first conductive layer (for example, SD1) and the second conductive layer (for example, SD2), and the first organic layer PLN1 covers the first edge BY1 and the second edge BY2.

The material of the first organic layer PLN1 is not limited herein. For example, its material is a resin.

The configuration in which the first organic layer PLN1 covers the first edge BY1 and the second edge BY2 is referred to as an edge-wrapping configuration. For example, in FIG. 2, the region of the first organic layer PLN1 that covers the first edge BY1 is labeled as P-B2, and the region of the first organic layer PLN1 that covers the second edge BY2 is labeled as P-B1. Such an edge-wrapping configuration can excellently protect the traces located within the edge region of the displaying base board, thereby preventing the gas or liquid in the subsequent fabricating process of the displaying base board from corroding the edges of the traces, to improve the reliability of the displaying base board.

In at least one embodiment of the present application, as shown in FIG. 4, the peripheral region BB comprises a first peripheral sub-region B1, a second peripheral sub-region B3 and a transition sub-region B2 connecting the first peripheral sub-region B1 and the second peripheral sub-region B3. The first peripheral sub-region B1 comprises a plurality of shift-register units, and the second peripheral sub-region B3 comprises a bonding electrode DJ. Within the second peripheral sub-region B3 and part of the transition sub-region B2, as shown in FIG. 8, in the direction perpendicular to the plane where the substrate is located, the height of the first blocking part Dam1 is less than the height of the second blocking part Dam2.

FIG. 5 and FIG. 6 are partially enlarged views of the transition sub-region B2 in FIG. 4. FIG. 7 is a cross-sectional view along a direction A3A4 of FIG. 6. FIG. 8 is a cross-sectional view along a direction A5A6 of FIG. 6.

As an example, within the transition sub-region B2 and the second peripheral sub-region B3, both of the first blocking part Dam1 and the second blocking part Dam2 comprise at least two organic film layers and at least one conductive layer, for example, at least two of the first organic layer PLN1, the second organic layer PLN2, the pixel defining layer PDL and the buffer layer PS, and, for example, at least one of the first source-drain metal layer SD1 and the second source-drain metal layer SD2.

The transition sub-region B2 comprises a first region B2-1 and a second region B2-2 that are connected, the first region B2-1 is connected to the first peripheral sub-region B1, and the second region B2-2 is connected to the second peripheral sub-region B2.

As an example, within some of the regions of the transition sub-region B2, the quantity of the film layers comprised by the first blocking part Dam1 is less than or equal to the quantity of the film layers comprised by the second blocking part Dam2.

For example, as shown in FIG. 7, within the first region B2-1 of the transition sub-region B2, the quantity of the film layers comprised by the first blocking part Dam1 is 5 layers, the quantity of the film layers comprised by the second blocking part Dam2 is 4 layers, and the height of the first blocking part Dam1 is substantially equal to the height of the second blocking part Dam2.

For example, as shown in FIG. 8, within the second region B2-2 of the transition sub-region B2, the quantity of the film layers comprised by the first blocking part Dam1 is 3 layers, the quantity of the film layers comprised by the second blocking part Dam2 is 4 layers, and the height of the first blocking part Dam1 is less than the height of the second blocking part Dam2.

It should be noted that a grid layer, an active layer and a grid insulating layer may be provided between the substrate 100 and the first conductive layer (for example, the first source-drain metal layer SD1). The film-layer structures between the substrate 100 and the first conductive layer are not limited herein, and may be decided particularly according to product designs.

In an exemplary embodiment, the height of the first blocking part Dam1 may be reduced by removing the first organic layer PLN1 within the region where the first blocking part Dam1 is located.

In the embodiment of the present application, because, within the transition sub-region B2 and the second peripheral sub-region B3, the room between the edge of the active area AA and the edge of the displaying base board is larger than the room within the first peripheral sub-region B1, within the transition sub-region B2 and the second peripheral sub-region B3, the possibility with which the ink flows out of the edge of the displaying base board is reduced. Therefore, in this case, it may be configured that, in the direction perpendicular to the plane where the substrate 100 is located, the height of the first blocking part Dam1 is less than the height of the second blocking part Dam2. Accordingly, the consumption of the organic material within the peripheral region BB is reduced, thereby reducing the risk in abnormality of the displaying base board caused by the gas generated by the organic material. In addition, within the second peripheral sub-region B3 a plurality of signal lines (for example, the FMLOC traces) connected to the bonding electrode DJ are provided, and, by configuring that the height of the first blocking part Dam1 is less than the height of the second blocking part Dam2, not only the effect of blocking the printed ink is ensured, but also the flatness of that region is increased, thereby reducing the risk in line breakage of the signal lines within that region, to further improve the reliability of the displaying base board.

In at least one embodiment of the present application, as shown in FIG. 5, the transition sub-region B2 comprises a first region B2-1 and a second region B2-2 that are connected, the first region B2-1 is connected to the first peripheral sub-region B1, and the second region B2-2 is connected to the second peripheral sub-region B2. The first conductive part VSS-1 extends from the first peripheral sub-region B1 to the first region B2-1, and the second conductive part VSS-2 extends from the first peripheral sub-region B1 to the first region B2-1, the second region B2-2 and the second peripheral sub-region B3.

In an exemplary embodiment, as shown in FIG. 5, the transition sub-region B2 further comprises an initializing signal line Vini, wherein the part of the initializing signal line Vini that is located in the first conductive layer (for example, the layer SD1) comprises two line segments Vini-L1, Vini-L2, and the two line segments Vini-L1, Vini-L2 are connected to each other by a connecting line (not shown) located at the grid layer.

In an exemplary embodiment, as shown in FIG. 5, the transition sub-region B2 further comprises a second power-supply signal line, for example, the line VDD, wherein the second power-supply signal line is located within the region between the first power-supply signal line and the active area AA, the part of the second power-supply signal line that is located within the transition sub-region B2 is provided in the second conductive layer (for example, the layer SD2), and the second power-supply signal line is provided with a plurality of openings arranged in an array.

In the embodiment of the present application, as shown in FIG. 5, within the second peripheral sub-region B3 and part of the transition sub-region B2, by removing the first organic layer PLN1 within the region where the first blocking part Dam1 is located, if the height of the first blocking part Dam1 is less than the height of the second blocking part Dam2, when the first conductive part VSS-1 extends into the second peripheral sub-region B3, because the removal of the first organic layer PLN1 adjacent to the first blocking part Dam1 causes the edge of the first conductive part VSS-1 to be incapable of the edge-wrapping configuration, it is configured that the first conductive part VSS-1 extends from the first peripheral sub-region B1 to the first region B2-1, and is disconnected at the second region B2-2, to prevent abnormality of the displaying base board caused by an increased risk in corrosion of the first conductive part VSS-1.

In at least one embodiment of the present application, as shown in FIG. 5, on the side of the first region B2-1 that is close to the second region B2-2, the line width of the first conductive part VSS-1 gradually decreases in the direction from the first region B2-1 pointing to the second region B2-2.

It should be noted that, in the description, the “line width” refers to the width of a signal line in the direction perpendicular to its extension direction, which is not discussed further.

In the displaying base board according to the embodiments of the present application, by configuring that the line width of the first conductive part VSS-1 gradually decreases in the direction from the first region B2-1 pointing to the second region B2-2, and is disconnected at the boundary between the first region B2-1 and the second region B2-2, in an aspect, it is prevented that the first conductive part VSS-1 is provided near the position of the lower border frame (the second peripheral region B3), which results in the increasing of the probability of its corrosion, to cause abnormality. In another aspect, the gradual reducing of its line width prevents heat accumulation (the heat generated by the resistance) within the local region caused by sudden increasing of the resistance of the first power-supply signal line, thereby preventing short circuiting or open circuiting of the leads in the displaying base board due to ignition.

In at least one embodiment of the present application, as shown in FIG. 5, on the side of the first region B2-1 that is close to the second region B2-2, the line width of the second conductive part VSS-2 gradually decreases in the direction from the first region B2-1 pointing to the second region B2-2.

In at least one embodiment of the present application, as shown in FIG. 5, within the first region B2-1, the amplitude of the decreasing of the line width of the first conductive part VSS-1 and the amplitude of the decreasing of the line width of the second conductive part VSS-2 are consistent.

That the “amplitudes of the decreasing are equal” includes but is not limited to that the “amplitudes of the decreasing are equal”. Because of the fluctuation in the process, all of the variations in which the amplitude of the decreasing of the line width of the first conductive part VSS-1 and the amplitude of the decreasing of the line width of the second conductive part VSS-2 differ in the range of 10% fall within the “amplitudes of the decreasing are equal”. For example, the difference between the amplitudes of the decreasing of the line widths of them is 2%, 3%, 4%, 5%, 6%, 7%, 8% and 9%.

As an example, as shown in FIG. 5, the slopes of a fifth edge BY5 of the first conductive part VSS-1 and a sixth edge BY6 of the second conductive part VSS-2 may be equal.

In the embodiment of the present application, within the first region B2-1, by configuring that the line width of the first conductive part VSS-1 and the line width of the second conductive part VSS-2 gradually decrease, and the amplitudes of the decreasing of the line widths of them are consistent, it is ensured that the resistance of the first power-supply signal line stably increases, to prevent heat accumulation within the local region caused by sudden increasing of the resistance, thereby improving the reliability of the displaying base board.

In at least one embodiment of the present application, as shown in FIG. 5, the first power-supply signal line further comprises a third conductive part VSS-3, the third conductive part VSS-3 extends from the second region B2-2 to the second peripheral sub-region B3, and the third conductive part VSS-3 is located at the second conductive layer (for example, the layer SD2), and is connected to the second conductive part VSS-2. The orthographic projection of the third conductive part VSS-3 on the substrate 100 partially overlaps with the orthographic projection of the second blocking part Dam2 on the substrate 100, and the second blocking part Dam2 is located at the boundary between the second conductive part VSS-2 and the third conductive part VSS-3. Within the second region B2-2, the line width of the third conductive part VSS-3 gradually increases in the direction from the second region B2-2 pointing to the second peripheral sub-region B3.

In an exemplary embodiment, as shown in FIG. 5, the line width of the part of the second conductive part VSS-2 that is located within the second region B2-2 gradually decreases.

In at least one embodiment of the present application, as shown in FIG. 5, within the second region B2-2, the amplitude of the increasing of the line width of the third conductive part VSS-3 and the amplitude of the decreasing of the line width of the second conductive part VSS-2 are consistent.

As an example, all of the variations in which the amplitude of the increasing of the line width of the third conductive part VSS-3 and the amplitude of the decreasing of the line width of the second conductive part VSS-2 differ in the range of 10% fall within the “amplitudes of the decreasing are equal”. For example, the difference between the amplitudes of the decreasing of the line widths of them is 2%, 3%, 4%, 5%, 6%, 7%, 8% and 9%.

For example, as shown in FIG. 5, the slopes of the sixth edge BY6 of the second conductive part VSS-2 and a seventh edge BY7 of the third conductive part VSS-3 may be equal.

In the embodiment of the present application, by configuring that the line width of the third conductive part VSS-3 gradually increases, the resistance of the first power-supply signal line can be reduced, which compensates for the loss in the electric conductivity caused by the disconnection of the first conductive part VSS-1 within the second region B2-2 and the second peripheral sub-region B3 to a large extent, balances the resistances of the first power-supply signal line at different positions, and improves the resistance stability of the first power-supply signal line, thereby improving the quality of the displaying base board.

In at least one embodiment of the present application, within the first region B2-1, the orthographic projection of the first conductive part VSS-1 on the substrate 100 partially overlaps with the orthographic projection of the first blocking part Dam1 on the substrate 100, and the first conductive part VSS-1 is located on the side of the first blocking part Dam1 that is close to the active area AA. The region enclosed by the orthographic projections on the substrate 100 of the outer contours of some of the openings (for example, SD2-H) falls within the region of the orthographic projection of the first blocking part Dam1 on the substrate 100. The region enclosed by the orthographic projections on the substrate 100 of the outer contours of some of the openings falls within the region of the second conductive part VSS-2 that does not overlap with the orthographic projection of the first conductive part VSS-1 on the substrate 100.

As an example, as shown in FIG. 5, the lower edge (a lateral side close to the edge of the displaying base board) of the first conductive part VSS-1 overlaps with the first blocking part Dam1. In order to improve the capacity of corrosion resistance of the upper edge and the lower edge of the first conductive part VSS-1, both of the part of the first conductive part VSS-1 that is located within the first region B2-1 and the part of the first conductive part VSS-1 that is located within the first peripheral sub-region B1 are provided with edge wrapping.

Regarding the first conductive part VSS-1 located within the first region B2-1, as shown in FIG. 5, both of its upper edge and lower edge (the fifth edge BY5 are connected to the upper edge and the lower edge) are covered by the first organic layer PLN1. Moreover, in order to facilitate the gases generated by the organic materials (for example, the material of the first organic layer PLN1) of the displaying base board to be released, openings (for example, SD2-H) arranged in an array are provided in the second conductive layer (for example, the layer SD2) overlapping with the first organic layer PLN1.

In at least one embodiment of the present application, both of the regions of the peripheral region BB that have an overlapping part with the first organic layer PLN1 and the second conductive layer SD2 may be provided with a plurality of openings (for example, SD2-H), thereby increasing the amount of the released gases generated by the organic materials of the displaying base board to a large extent, to prevent abnormality of displaying caused by the gases sealed in the displaying base board.

In at least one embodiment of the present application, within the first region B2-1 of the transition sub-region B2, the film-layer structures comprised by the first blocking part Dam1 are as follows:
as shown in FIG. 7, part (located at the first conductive layer SD1) of the first conductive part VSS-1 located on the substrate 100, part of the first organic layer PLN1 covering the lower edge of the first conductive part VSS-1, part (located at the second conductive layer SD2) of the second conductive part VSS-2, part of the second organic layer PLN2, and part of the pixel defining layer PDL covering the second organic layer PLN2.

As shown in FIG. 7, within the first region B2-1 of the transition sub-region B2, the film-layer structures comprised by the second blocking part Dam2 are as follows:
part of the first organic layer PLN1; and
part of the second conductive part VSS-2, part of the second organic layer PLN2 and part of the pixel defining layer PDL that are located on the first organic layer PLN1 and are sequentially arranged.

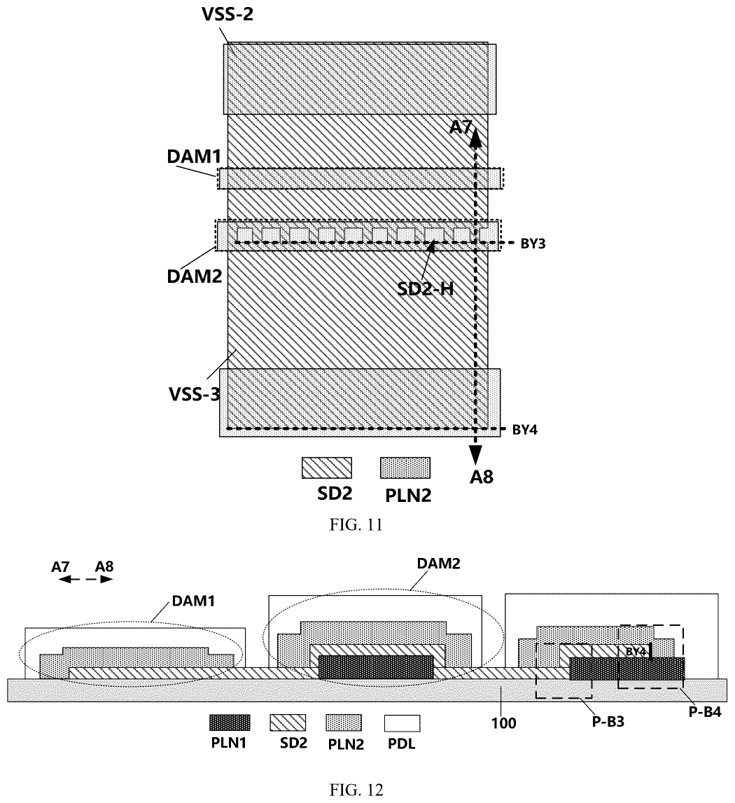

In at least one embodiment of the present application, within the second peripheral sub-region B3 and the second region B2-2 of the transition sub-region B2, the film-layer structures comprised by the first blocking part Dam1 are as follows:
as shown in FIG. 8 and FIG. 12, part (located at the second conductive layer SD2) of the second conductive part VSS-2 located on the substrate 100, part of the second organic layer PLN2, and part of the pixel defining layer PDL covering the second organic layer PLN2; and
the film-layer structures comprised by the second blocking part Dam2 are as follows:
as shown in FIG. 8 and FIG. 12, part of the first organic layer PLN1; and
part (located at the second conductive layer SD2) of the second conductive part VSS-2, part of the second organic layer PLN2 and part of the pixel defining layer PDL that are located on the first organic layer PLN1 and are sequentially arranged.

It should be noted that FIG. 8 is a schematic cross-sectional view of the blocking parts located within the second region B2-2 of the transition sub-region B2. FIG. 12 is a schematic cross-sectional view of the blocking parts located within the second peripheral sub-region B3; in other words, FIG. 12 is a schematic cross-sectional view along a direction A7A8 of FIG. 11.

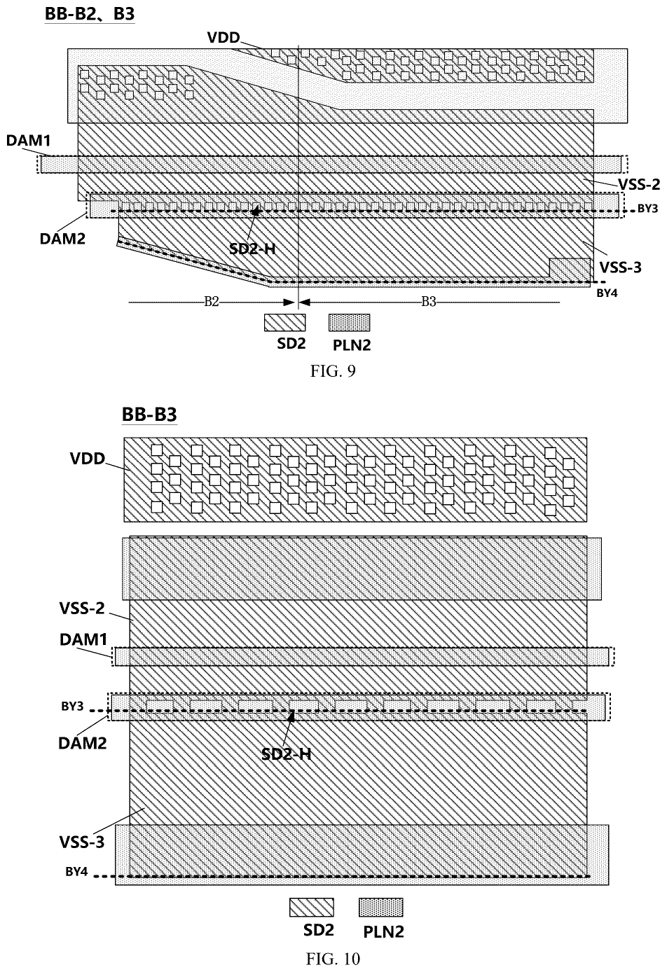

In at least one embodiment of the present application, referring to FIG. 6 and FIG. 9, within the second region B2-2 and the second peripheral sub-region B3, the region enclosed by the orthographic projections on the substrate 100 of the outer contours of some of the openings (for example, SD2-H) falls within the orthographic projection of the second conductive part VSS-2 on the substrate. The region enclosed by the orthographic projections on the substrate 100 of the outer contours of some of the openings (for example, SD2-H) falls within the region of the orthographic projection of the second blocking part Dam2 on the substrate 100.

In at least one embodiment of the present application, referring to FIG. 9, FIG. 10 and FIG. 11, the third conductive part VSS-3 comprises a third edge BY3 and a fourth edge BY4, the third edge BY4 is close to the active area AA, the fourth edge BY4 is away from the active area AA, and the orthographic projection of the third edge BY3 on the substrate 100 and the orthographic projection of the second blocking part Dam2 on the substrate 100 overlap. The displaying base board further comprises the second organic layer PLN2 located on the side of the second conductive layer (for example, the layer SD2) away from the substrate 100, and the second organic layer PLN2 covers the third edge BY3 and the fourth edge BY4.

In addition, the configuration in which the second organic layer PLN2 covers the third edge BY3 and the fourth edge BY4 is referred to as an edge-wrapping configuration, as shown by, for example, the rectangular dotted-line blocks labeled as P-B3 and P-B4 in FIG. 12, wherein the region within which the second organic layer PLN2 covers the third edge BY3 is labeled as P-B3, and the region within which the second organic layer PLN2 covers the fourth edge BY4 is labeled as P-B4. Such an edge-wrapping configuration can excellently protect the traces located within the edge region of the displaying base board, thereby preventing the gas or liquid in the subsequent fabricating process of the displaying base board from corroding the edges of the traces, and reducing the risk in water-vapor penetration at the edge position of the displaying base board, to improve the reliability of the displaying base board.

It should be noted that, in an embodiment of the present application, the second organic layer PLN2 may comprise two parts, i.e., a first part and a second part. The structure of the part of the second organic layer PLN2 that is located in the second blocking part Dam2 shown in FIG. 7 will be taken as an example for the description. The height of the first part is greater than the height of the second part. The second part is fabricated by using a half-tone mask, whereby the upper surface of the part of the second organic layer PLN2 that is located in the second blocking part Dam2 is of a step shape. In at least one embodiment of the present application, the second organic layer PLN2 used for the edge-wrapping configuration is fabricated by using a half-tone mask.

An embodiment of the present application provides a displaying device, wherein the displaying device comprises the displaying base board stated above.

The particular structure of the displaying base board comprised by the displaying device is not discussed further herein, and may particularly refer to the embodiments described above.

The displaying device may be a displaying device such as an LCD display, and any product or component having the function of displaying and comprising the displaying device, such as a television set, a digital camera, a mobile phone and a tablet personal computer.

The displaying device according to the embodiments of the present application comprises the displaying base board stated above. In the displaying base board, by configuring that the orthographic projection of the first power-supply signal line, for example, the line VSS, on the substrate 100 of the displaying base board has an overlapping part with individually the orthographic projection of the first blocking part Dam1 on the substrate 100 and the orthographic projection of the second blocking part Dam2 on the substrate 100, the size of the first power-supply signal line is increased, the electric conductivity of the first power-supply signal line is increased, and the resistance of the first power-supply signal line is reduced, thereby improving the effect of the signal transmission in the first power-supply signal line. By providing the plurality of openings (for example, those labeled as SD2-H) in the first power-supply signal line, for example, the line VSS, and configuring that the region enclosed by the orthographic projections on the substrate 100 of the outer contours of some of the openings falls within the region of the orthographic projection on the substrate 100 of at least one of the first blocking part Dam1 and the second blocking part Dam2, the gases (Bubble) generated by the organic materials of the first blocking part Dam1 and the second blocking part Dam2 can be released out of the openings, thereby preventing the first power-supply signal line, for example, the line VSS, from sealing the gases generated by the organic materials to result in abnormality of the displaying base board.

The above are merely particular embodiments of the present application, and the protection scope of the present application is not limited thereto. All of the variations or substitutions that a person skilled in the art can easily envisage within the technical scope disclosed by the present application should fall within the protection scope of the present application. Therefore, the protection scope of the present application should be subject to the protection scope of the claims.

1. A displaying base board, wherein the displaying base board comprises an active area and a peripheral region located on one side of the active area, the peripheral region comprises at least a first blocking part and a second blocking part, and the second blocking part is located on one side of the first blocking part away from the active area;
the peripheral region further comprises a first power-supply signal line, and an orthographic projection of the first power-supply signal line on a substrate of the displaying base board has an overlapping part with individually an orthographic projection of the first blocking part on the substrate and an orthographic projection of the second blocking part on the substrate; and
the first power-supply signal line is provided with a plurality of openings, and a region enclosed by orthographic projections on the substrate of outer contours of some of the openings falls within a region of the orthographic projection on the substrate of at least one of the first blocking part and the second blocking part.

2. The displaying base board according to claim 1, wherein the displaying base board comprises a first conductive layer and a second conductive layer located on one side of the first conductive layer away from the substrate;
the first power-supply signal line comprises a first conductive part and a second conductive part, the first conductive part is located at the first conductive layer, the second conductive part is located at the second conductive layer, and an orthographic projection of the first conductive part on the substrate and an orthographic projection of the second conductive part on the substrate partially overlap; and
an area of an orthographic projection on the substrate of an outer contour of the second conductive part is greater than or equal to two times of an area of an orthographic projection on the substrate of an outer contour of the first conductive part.

3. The displaying base board according to claim 2, wherein the orthographic projection of the first conductive part on the substrate partially overlaps with the orthographic projection of the first blocking part on the substrate and the orthographic projection of the second blocking part on the substrate individually, and the orthographic projection of the second conductive part on the substrate partially overlaps with the orthographic projection of the first blocking part on the substrate and the orthographic projection of the second blocking part on the substrate individually.

4. The displaying base board according to claim 3, wherein in a direction perpendicular to a plane where the substrate is located, a height of the first blocking part is less than or equal to a height of the second blocking part.

5. The displaying base board according to claim 4, wherein the peripheral region comprises a first peripheral sub-region, the first peripheral sub-region is located on one side of the active area, the first peripheral sub-region comprises a plurality of shift-register units that are cascaded, and the first blocking part is located on one side of the shift-register units away from the active area; and
in the direction perpendicular to the plane where the substrate is located, a height of a part of the first blocking part that is located in the first peripheral sub-region is substantially equal to a height of a part of the second blocking part that is located in the first peripheral sub-region.

6. The displaying base board according to claim 5, wherein the first conductive part and part of a conducting component in the shift-register units are arranged in a same layer, and the second conductive part covers at least some of the shift-register units.

7. The displaying base board according to claim 6, wherein in the first peripheral sub-region, a region enclosed by orthographic projections on the substrate of outer contours of some of the openings falls within orthographic projections of the shift-register units on the substrate, and a region enclosed by orthographic projections on the substrate of outer contours of some of the openings falls within a region of the orthographic projection of the first blocking part on the substrate.

8. The displaying base board according to claim 6, wherein a part of the first conductive part that is located in the first peripheral sub-region comprises a first edge and a second edge, the first edge is close to the active area, the second edge is away from the active area, and an orthographic projection of the second edge on the substrate and an orthographic projection of the second blocking part on the substrate overlap; and
the displaying base board further comprises a first organic layer located between the first conductive layer and the second conductive layer, and the first organic layer covers the first edge and the second edge.

9. The displaying base board according to claim 4, wherein the peripheral region comprises a first peripheral sub-region, a second peripheral sub-region and a transition sub-region connecting the first peripheral sub-region and the second peripheral sub-region;
the first peripheral sub-region comprises a plurality of shift-register units, and the second peripheral sub-region comprises a bonding electrode; and
in the second peripheral sub-region and part of the transition sub-region, along the direction perpendicular to the plane where the substrate is located, the height of the first blocking part is less than the height of the second blocking part.

10. The displaying base board according to claim 9, wherein the transition sub-region comprises a first region and a second region that are connected, the first region is connected to the first peripheral sub-region, and the second region is connected to the second peripheral sub-region; and
the first conductive part extends from the first peripheral sub-region to the first region, and the second conductive part extends from the first peripheral sub-region to the first region, the second region and the second peripheral sub-region.

11. The displaying base board according to claim 10, wherein on one side of the first region that is close to the second region, a line width of the first conductive part gradually decreases in a direction from the first region pointing to the second region.

12. The displaying base board according to claim 11, wherein on the one side of the first region that is close to the second region, a line width of the second conductive part gradually decreases in the direction from the first region pointing to the second region.

13. The displaying base board according to claim 12, wherein in the first region, an amplitude of the decreasing of the line width of the first conductive part and an amplitude of the decreasing of the line width of the second conductive part are consistent.

14. The displaying base board according to claim 12, wherein the first power-supply signal line further comprises a third conductive part, the third conductive part extends from the second region to the second peripheral sub-region, and the third conductive part is located at the second conductive layer, and is connected to the second conductive part;
an orthographic projection of the third conductive part on the substrate partially overlaps with the orthographic projection of the second blocking part on the substrate, and the second blocking part is located at a boundary between the second conductive part and the third conductive part; and
in the second region, a line width of the third conductive part gradually increases in a direction from the second region pointing to the second peripheral sub-region.

15. The displaying base board according to claim 14, wherein in the second region, an amplitude of the increasing of the line width of the third conductive part and an amplitude of the decreasing of the line width of the second conductive part are consistent.

16. The displaying base board according to claim 14, wherein
in the first region, the orthographic projection of the first conductive part on the substrate partially overlaps with the orthographic projection of the first blocking part on the substrate, and the first conductive part is located on one side of the first blocking part that is close to the active area;
a region enclosed by orthographic projections on the substrate of outer contours of some of the openings falls within a region of the orthographic projection of the first blocking part on the substrate; and
a region enclosed by orthographic projections on the substrate of outer contours of some of the openings falls within a region of the second conductive part that does not overlap with the orthographic projection of the first conductive part on the substrate.

17. The displaying base board according to claim 14, wherein
in the second region and the second peripheral sub-region, a region enclosed by orthographic projections on the substrate of outer contours of some of the openings falls within the orthographic projection of the second conductive part on the substrate; and
a region enclosed by orthographic projections on the substrate of outer contours of some of the openings falls within a region of the orthographic projection of the second blocking part on the substrate.

18. The displaying base board according to claim 17, wherein
the third conductive part comprises a third edge and a fourth edge, the third edge is close to the active area, the fourth edge is away from the active area, and an orthographic projection of the third edge on the substrate and the orthographic projection of the second blocking part on the substrate overlap; and
the displaying base board further comprises a second organic layer located on one side of the second conductive layer away from the substrate, and the second organic layer covers the third edge and the fourth edge.

19. The displaying base board according to claim 5, wherein in the first peripheral sub-region, both of the first blocking part and the second blocking part comprise:
part of the first conductive part located on the substrate;
part of the first organic layer directly contacting the first conductive part; and
part of the second conductive part, part of the second organic layer, part of an anode layer, part of a pixel defining layer and part of a buffer layer that are located on the first organic layer and are sequentially arranged; and
in a region between the first blocking part and the second blocking part, the first conductive part and the second conductive part directly contact, and the second conductive part and the anode layer directly contact.

20. (canceled)

21. A displaying device, wherein the displaying device comprises the displaying base board according to claim 1.
